(19) United States
(12) Patent Application Publication
(10) Pub. No.: US 2009/0152563 A1
(43) Pub. Date: Jun. 18, 2009

(54) PHOTO-SENSOR AND MANUFACTURING METHOD FOR PHOTO-SENSOR

(75) Inventors: Masami Hayashi, Tokyo (JP); Yusuke Uchida, Kumamoto (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/333,454

(22) Filed: Dec. 12, 2008

(30) Foreign Application Priority Data
Dec. 17, 2007 (JP) 2007-324515

(51) Int. Cl. H01L 31/112; H01L 31/18

(52) U.S. Cl. 257/72; 438/73; 257/E31.079

(57) ABSTRACT

The present invention prevents disconnection of a source electrode and a drain electrode, taking account of adhesion with amorphous silicon. A photo-sensor according to the present invention is a photo-sensor having a TFT array substrate that has an element region in which thin film transistors are arranged in an array, the photo-sensor comprising a passivation film which is provided above the thin film transistor and in which a contact hole is formed, and a photo-diode which is connected to a drain electrode of the thin film transistor via the contact hole, wherein the passivation film and a gate insulation film are removed in the peripheral area outside the element region of the TFT array substrate, and the edge of the passivation film in the peripheral area is formed at the same position as the edge of the gate insulation film on the periphery of the substrate, or outside the edge of the gate insulation film.

### BACKGROUND OF THE INVENTION

1. Field of the Invention

The present invention relates to a photo-sensor, which is a flat panel having a TFT array substrate on which thin film transistors (hereafter TFT), used for photo-diodes for converting visible light into electric charges and switching elements, are arrayed in a matrix, and a manufacturing method thereof.

2. Description of Related Art

A photo-sensor, which is a flat panel, is widely used. A photo-sensor has a TFT array substrate on which photo-diodes, for performing photo-electric conversion of visible light and TFTs, are arrayed. For example, a photo-sensor is used for a contact image sensor and x-ray imaging display device. In particular, a flat panel x-ray imaging display device (hereafter FPD) is a promising device in applications for the medical industry. An FPD is constructed by installing a scintillator for converting x-ray into visible light on the TFT array substrate.

In the field of x-ray image diagnosis, precision image observation (still image) and real-time image observation (moving image) are used depending on the case. An x-ray film is mainly used even now to capture a still image. And an image pickup tube (image intensifier), where a photo-multiplier and CCD are combined, is used to capture a moving image. X-ray film has high spatial resolution but low sensitivity, whereby only a still image can be photographed. Also x-ray film requires development processing after being exposed, which makes it inferior in terms of quick use. The image pickup tube, on the other hand, has high sensitivity and allows capturing moving images, but has a low spatial resolution. Another shortcoming of an image pickup tube, which is a vacuum device, is a limitation in increasing the size of the device.

There are two types of FPD: an indirect conversion type which converts an x-ray into light by a scintillator, such as CsI, then converts the light into electric charges by a photo-diode; and a direct conversion type which directly converts an x-ray into electric charges by an x-ray detection element represented by Se. Compared with the direct conversion type, the indirect conversion type has higher quantum efficiency and a better signal-to-noise ratio. Therefore in the case of the indirect conversion type, radioscopy and photography are possible with lower exposure dosage. A structure and manufacturing method of an indirect conversion type FPD array substrate are disclosed in FIG. 9 of Japanese Unexamined Patent Application Publication No. 2004-63660 (patent document 1) and FIG. 4 of Japanese Unexamined Patent Application Publication No. 2004-48000 (patent document 2).

In the array substrate of FPD, formation of a photo-diode, which influences the sensitivity and noise of a photo-sensor, is critical. A photo-sensor is comprised of an amorphous silicon layer which is formed on an electrode. For example, if a photo-sensor is formed on an electrode which is on a same layer as a gate electrode, as in the case of Patent Document 1, the following problems occur. That is, if a lower electrode of the photo-diode is formed using a same material as the gate line, the lower electrode is damaged considerably by dry etching, since the gate electrode is on the lowest layer. This increases the leak current of the photo-diode.

The photo-sensor is also damaged by forming a source electrode layer 605 and drain electrode layer 606. This narrows the choice of materials. Also the number of masks increases and the margin of aperture dimensions decreases in order to connect the source electrode layer 605 and cathode electrode layer 609.

Patent Document 2 discloses how to avoid these problems. This document states that in some cases electrodes formed at the lower portion of the photo-sensor are formed on the electrode in the same layer as the source electrode and drain electrode of the thin film transistor.

In the case of forming FPD using a PIN type photo-sensor, the film thickness of amorphous silicon of the photo-sensor must be thick in order to enable real-time image observation. As a result, film stress increases. And the amorphous silicon floats at a location where adhesion of the amorphous silicon and underlayer film is weak. As a result, dust in the processing device increases, and defects due to deposits increase. It is generally known that the adhesion of amorphous silicon and silicon nitride is weak. In Patent Document 1, the silicon nitride (602, 614) at the TFT portion remains, as shown in FIG. 24, and all other silicon nitride is removed. Here 600 is a glass substrate, 601 is a gate electrode, 602 is an insulation layer, 603 is a channel layer, 604 is an amorphous silicon layer and 605 is a source electrode layer. As mentioned above, if the silicon nitride is completely removed, the source electrode 605 and drain electrode layer 606 must climb over the step difference of the gate insulation film 602. Disconnection of the source electrode 605 and drain electrode 606 at this step difference portion is therefore of concern. Hence it is indispensable to design a new structure to prevent the disconnection of the source electrode and drain electrode, while considering adhesion with the amorphous silicon.

### SUMMARY OF THE INVENTION

An aspect of the present invention is a photo-sensor having a TFT array substrate that has an element region in which thin film transistors are arrayed in an array, including: a passivation film which is provided above the thin film transistor and in which a contact hole is formed; and a photo-diode which is connected to a drain electrode of the thin film transistor via the contact hole, wherein the passivation film and a gate insulation film at the edge on the TFT array substrate are removed in a peripheral area outside the element region of the TFT array substrate, and the edge of the passivation film in the peripheral area is formed at the same position as the edge of the gate insulation film in the peripheral area of the substrate, or outside the edge of the gate insulation film.

An aspect of a manufacturing method for a photo-sensor according to the present invention is a manufacturing method for a photo-sensor having a TFT array substrate that has an element region in which thin film transistors are arranged in an array, and a peripheral area outside the element region, the method including: a step of forming a thin film transistor on the substrate; a step of forming a passivation film having a contact hole on a drain electrode of the thin film transistor; and a step of forming a photo-sensor on the passivation film, wherein the passivation film and a gate insulation film at the of the substrate are removed in a peripheral area outside the element region where the thin film transistor is formed on the substrate, and the edge of the passivation film in the peripheral area is formed at the same position as the edge of the gate insulation film in the peripheral area of the substrate, or outside the edge of the gate insulation film.

According to an aspect of the photo-sensor of the present invention, adhesion at the substrate edge of the TFT array substrate improves and peeling of the amorphous silicon film can be prevented when the amorphous silicon layer, constituting the photo-diode of the photo-sensor, is formed. Also in the photolithography after forming the amorphous silicon film, contamination of the processing device, due to peeling of the amorphous silicon film and pattern defects due to reattached foreign substances of the peeled amorphous silicon film, can be prevented, so a panel with very few defects can be implemented even in a large sized photo-sensor.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view depicting a TFT array substrate of a photo-sensor according to Embodiment 1;

FIG. 2 is a cross-sectional view depicting the TFT array substrate of the photo-sensor according to Embodiment 1;

FIG. 3 is a plan view depicting an edge portion of the TFT array substrate used for the photo-sensor according to Embodiment 1;

FIG. 4 is a cross-sectional view depicting an edge portion of the TFT array substrate used for the photo-sensor according to Embodiment 1;

FIG. 5A to FIG. 5D are cross-sectional views depicting manufacturing steps for the substrate edge of the TFT array substrate used for the photo-sensor according to Embodiment 1;

FIG. 6A to FIG. 6C are cross-sectional views depicting manufacturing steps of the TFT array substrate used for the photo-sensor according to Embodiment 1;

FIG. 7A to FIG. 7C are cross-sectional views depicting manufacturing steps for the edge of the TFT array substrate used for the photo-sensor according to Embodiment 1;

FIG. 8A and FIG. 8B are cross-sectional views depicting manufacturing steps of the TFT array substrate used for the photo-sensor according to Embodiment 1;

FIG. 9A and FIG. 9B are cross-sectional views depicting manufacturing steps for the edge of the TFT array substrate used for the photo-sensor according to Embodiment 1;

FIG. 10A and FIG. 10B are cross-sectional views depicting manufacturing steps for the terminal portion of the TFT array substrate used for the photo-sensor according to Embodiment 1;

FIG. 11A and FIG. 11B are cross-sectional views depicting manufacturing steps for the terminal portion of the TFT array substrate used for the photo-sensor according to Embodiment 1;

FIG. 12A and FIG. 12B are cross-sectional views depicting a substrate edge portion of another example of the TFT array used for the photo-sensor according to Embodiment 1;

FIG. 13 is a plan view depicting a TFT array substrate used for a photo-sensor according to Embodiment 2;

FIG. 14 is a cross-sectional view depicting the TFT array substrate used for the photo-sensor according to Embodiment 2;

FIG. 15A and FIG. 15B are cross-sectional views depicting manufacturing steps for the TFT array substrate used for the photo-sensor according to Embodiment 2;

FIG. 16 is a plan view depicting the TFT array substrate and the substrate of another example used for the photo-sensor according to Embodiment 2;

FIG. 17 is a cross-sectional view depicting the TFT array substrate and the substrate of another example used for the photo-sensor according to Embodiment 2;

FIG. 18A to FIG. 18C are cross-sectional views depicting manufacturing steps for a TFT array substrate used for a photo-sensor according to Embodiment 3;

FIG. 19A to FIG. 19C are cross-sectional views of the substrate edge depicting manufacturing steps for the TFT array substrate used for the photo-sensor according to Embodiment 3;

FIG. 20 is a cross-sectional view of the substrate edge portion depicting other manufacturing steps of the TFT array substrate used for the photo-sensor according to Embodiment 3;

FIG. 21 is a cross-sectional view depicting a photo-sensor having a scintillator;

FIG. 22 shows a configuration of a photo-sensor having a digital board and a driver board.

FIG. 23 shows a configuration of an x-ray imaging display device; and

FIG. 24 is a cross-sectional view depicting the TFT array substrate according to Patent Document 1.

### DESCRIPTION OF THE PREFERRED EMBODIMENTS

### Embodiment 1

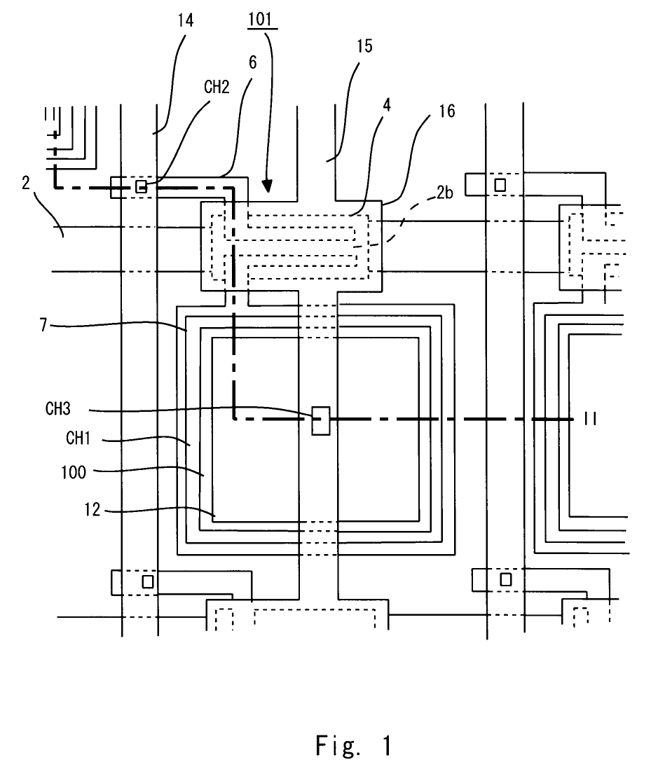

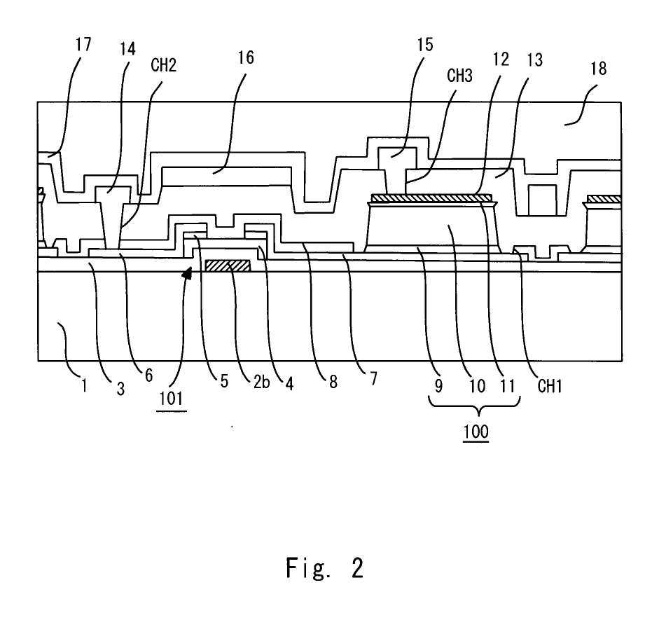

An embodiment of the present invention will now be described with reference to drawings. FIG. 1 is a plan view depicting a TFT array substrate used for a photo-sensor according to the present embodiment. FIG. 2 is a cross-sectional view sectioned at II-II in FIG. 1. In the TFT array substrate, light receiving pixels are arranged in an array. Each pixel has one photo-diode 100 and one thin film transistor (hereafter TFT) 101. In other words, the photo-diode 100 and TFT 101 are arranged in an array on the substrate. Here an area where the photo-diode 100 and TFT 101 are arranged in an array is regarded as an “element region”, and an area outside thereof is regarded as a “peripheral area”. For example, the element region is formed to be rectangular, and the peripheral area is formed to be a frame shape. The peripheral area is formed outside the terminal portions of the lines formed in the element region. Therefore the element region is disposed at the center of the substrate, and the terminal area, where terminals of the lines are formed, is disposed outside the element region. The peripheral area is disposed outside the terminal area.

A plurality of gate lines 2 for driving the TFT 101 are formed on the substrate. The gate line 2 includes a plurality of gate electrodes 2b. A plurality of data lines 14 are also formed on the substrate. Out of the gate lines 2, portions constituting the TFT 101 are the gate electrode 2b. A data line 14 is connected to a source electrode 6. In FIG. 1, the plurality of gate lines 2 are formed horizontally, and the data line 14 is formed vertically. The gate electrode 2b and the source electrode 6 are crossed with a gate insulation film 3 interposed therebetween. The plurality of gate lines 2 are disposed in parallel (FIG. 1). The plurality of data lines 14 are disposed in parallel. The gate line 2 supplies a gate signal to the TFTs 101 which are arranged in a row horizontally. By this, one row of TFTs 101 is simultaneously turned ON. The data line 14 reads data sequentially from a plurality of TFTs 101 arranged in a column vertically. An area surrounded by adjacent gate lines 2 and adjacent data lines 14 is a light receiving pixel area. Therefore the photo-sensor is a two-dimensional array photo-detector.

The gate lines 2, made of metal, are formed on a glass substrate 1, which is an insulation substrate. The main component of the gate line 2 is Al (aluminum), which is a low resistance metal material. For a metal of which main component is Al, an Al alloy containing Ni, that is an Al—Ni alloy, can be used. For an Al—Ni alloy, AlNiNd, AlNiSi or AlNiMg, for example, can be used. Another Al alloy may be used for the gate line 2. For the gate line 2, another low resistance metal material, such as Cu, may be used instead of Al. The gate line 2 is not limited to a single layer of low resistance metal material, but a layered film of low resistance metal material and another metal material, for example, may be used. The gate insulation film 3 is formed as the cover of the gate electrode 2b. A semiconductor layer 4 is formed on the gate insulation film 3 so as to face the gate electrode 2b. The semiconductor layer 4 is made of amorphous silicon to which hydrogen atoms are added (hereafter called the a-Si:H layer). The ohmic contact layer 5 is formed on this semiconductor layer 4. The ohmic contact layer 5 is an a-Si:H layer to which n type impurities are doped at high density (hereafter called the n+a-Si:H layer).

The TFT 101 is disposed near the intersection of the data line 14 and the gate line 2. The TFT 101 has the semiconductor layer 4, ohmic contact layer 5, gate electrode 2b, gate insulation film 3, source electrode 6 and drain electrode 7. Here the semiconductor layer 4 has a channel area, source area and drain area. The channel area is disposed between the source area and drain area. The ohmic contact layer 5 is formed on the source area and drain area. The source electrode 6 is formed on the source area, and the drain electrode 7 is formed above the drain area.

The source electrode 6 and the drain electrode 7 are connected with the semiconductor layer 4 via the ohmic contact layer 5. A first passivation film 8 is formed so as to cover the source electrode 6 and the drain electrode 7. A contact hole CH1 is formed in the first passivation film 8. The photo-diode 100 is formed so as to be connected with the drain electrode 7 via the opening of the contact hole CH1.

The photo-diode 100, which is roughly rectangular, is formed at the center of the light receiving area. This photo-diode 100 becomes the light receiving pixel. The photo-diode 100 has a three-layer structure. The photo-diode 100 has amorphous silicon films 9, 10 and 11 in sequential order from the glass substrate 1 side. P (phosphorus) is doped in the amorphous silicon film 9. The amorphous silicon film 10 is intrinsic. B (boron) is doped in the amorphous silicon film 11. The photo-diode 100 is formed on the drain electrode 7, and is connected with the drain electrode 7. In concrete terms, the contact hole CH1 is formed in the first passivation film 8 on the drain electrode 7. Then the amorphous silicon 9 is formed in the contact hole CH1. The photo-diode 100 is formed so as to be enclosed by the contact hole CH1. A transparent electrode 12, made of IZO, ITZO or ITSO, for example, is formed on the top layer of the amorphous silicon 11. The photo-diode 100, constructed like this, converts received light into electric charges.

A second passivation film 13 is formed so as to cover the photo-diode 100 and TFT 101. Contact holes CH2 and CH3 are formed in the second passivation film 13. The contact hole CH2 penetrates the first passivation film 8 and the second passivation film 13. The data line 14 on the second passivation film 13 is connected with the source electrode 6 via the contact hole CH2. A bias line 15 on the second passivation film 13 is connected with the transparent electrode 12 via the contact hole CH3. An Al—Ni alloy film is formed at least on the top layer or bottom layer of the data line 14 and the bias line 15. The data line 14 and the bias line 15 may be a single layer of Al—Ni alloy film. If the top layer is an Al—Ni alloy film, the surface thereof may be a nitride layer.

The data line 14 is a line for reading electric charges converted by the photo-diode 100, which has a three-layer structure. The bias line 15 is a line for applying reverse bias to the photo-diode 100 having the three-layer structure in order to generate an OFF state when light is not received. A light shielding layer 16 for shielding light for the TFT 101 is formed on the second passivation film 13. The light shielding layer 16 is formed using a wide portion of the bias line 15. And a third passivation film 17 is formed so as to cover the second passivation film 13, light shielding layer 16, data line 14 and bias line 15. A fourth passivation film 18 is formed on the third passivation film 17. Here the fourth passivation film 18 is a film of which surface is flat, and is made of organic resin, for example.

The bias line 15 is formed between the data lines 14. In other words, the data line 14 and the bias line 15 are alternately disposed. The data lines 14 and the bias lines 15 are formed in parallel. Therefore the bias lines 15 crosses with the gate lines 2. At the intersection with the gate line 2, the bias line 15 is formed to be wide, so as to cover the TFT 101. The bias line 15 is formed so as to pass on the photo-diode 100. The bias line 15 is connected with the transparent electrode 12 on the photo-diode 100, and supplies the reverse bias voltage to the photo-diode 100.

In a photo-sensor constructed like this, the data line 14 reads electric charges from the photo-diode 100 via the TFT 101. In concrete terms, TFT 101 is turned ON by the gate signal which is supplied to the gate line 2. By this, electric charges are read to the data line 14 via the TFT 101.

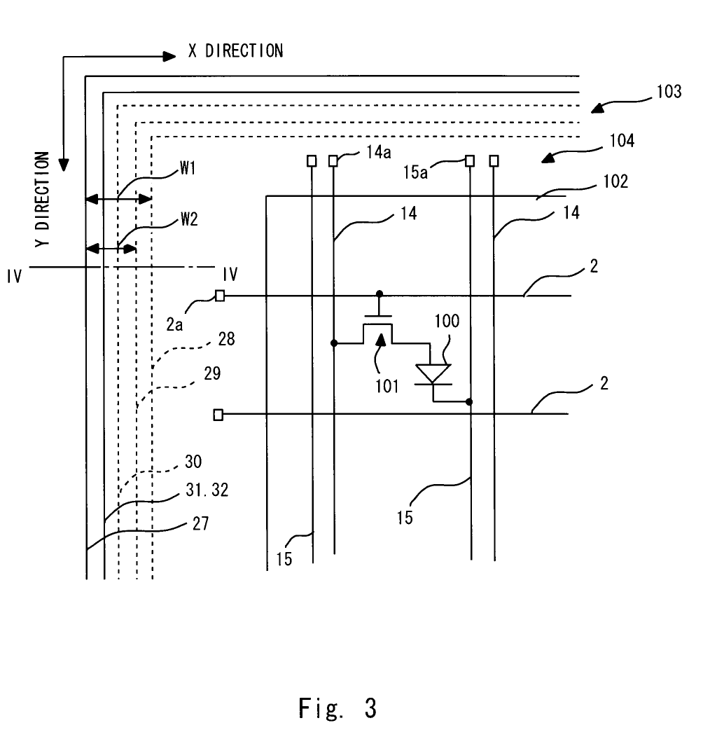

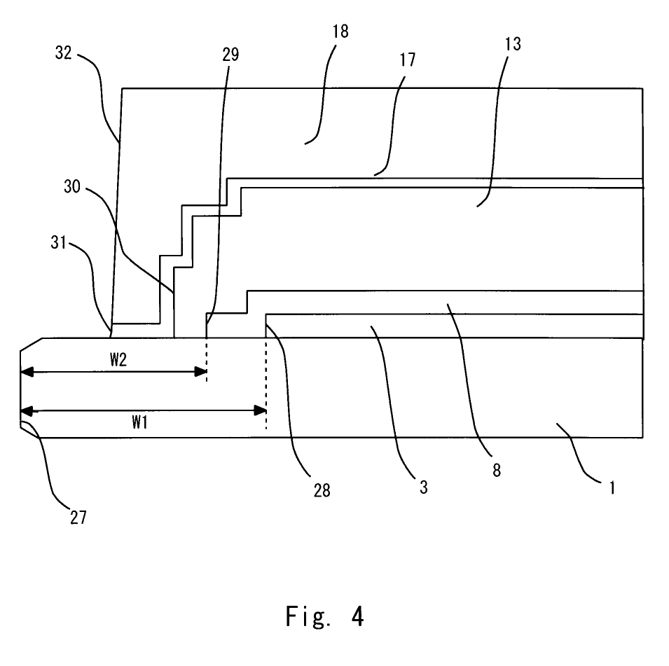

Now a TFT array substrate edge portion will be described with reference to FIG. 3 and FIG. 4. FIG. 3 is a front view of the TFT array substrate. And FIG. 4 is a cross-sectional view of the TFT array substrate. The photo-diode 100 and the TFT 101 are arranged on the substrate in an array. In the TFT 101, the source is connected to the data line 14, the gate is connected to the gate line 2, and the drain is connected to the photo-diode 100. The area where the photo-diode 100 and the TFT 101 are arranged in an array is the element region 102. FIG. 3 shows the upper left corner of the element region 102 which is formed as a rectangle. Frame-shaped terminal area 104 is formed outside the element region 102. In the terminal area 104, the gate terminal 2a of the gate line 2, data terminal 14a of the data line 14 and bias terminal 15a of the bias line 15 are disposed. These terminals are formed near the edge of each line. In other words, the portion of the line which leads outside the element region 102 becomes a terminal. Each terminal is exposed to the front face side, and is connected to external lines. A short ring line may be formed outside each terminal. Outside the terminal area 104 becomes the peripheral area 103. Therefore the terminal area 104 is disposed between the peripheral area 103 and the element region 102. The peripheral area 103 is formed to be a frame shape. In the peripheral area 103, the gate insulation film 3 and the first passivation film 8 at the edge of the glass substrate 1 are removed.

The gate insulation film 3 is formed on the glass substrate 1, which is an insulation substrate. A portion of the gate insulation film 3, with width W1 from the substrate edge 27, is removed. In other words, a gate insulation film removal area, which has width W1 where the gate insulation film is not formed, is created around the gate insulation film 3. This gate insulation film removal area is formed all around the glass substrate 1. In other words, the gate insulation film 3 has an edge 28. And the first passivation film 8 is formed so as to cover the gate insulation film 3. A portion of the first passivation film 8, with width W2 from the substrate edge 27, is removed, that is, a first passivation removal area, which has width W2, is created. The first passivation removal area is formed all around the glass substrate 1. In other words, the first passivation film 8 has an edge 29. The first passivation film 8 is formed so as to extend beyond the edge 28 of the gate insulation film 3. This means that the first passivation film 8 is formed to extend from the gate insulation film 3. The relationship of width W1 and width W2 is W1≧W2. That is, the edge 29 exists between the substrate edge 27 and the edge 28 all around the glass substrate 1. In other words, the edge 29 is formed outside the edge 28. The second passivation film 13, the third passivation film 17 and the fourth passivation film 18 are formed thereon.

An edge 30 is formed in the second passivation film 13. An edge 31 is formed in the third passivation film 17. And an edge 32 is formed in the fourth passivation film 18. The edges 30, 31 and 32 of the second passivation film 13, the third passivation film 17 and the fourth passivation film 18 are formed at arbitrary positions. Here the edges along the Y direction, with respect to the glass substrate 1, are described, but for the edges in the X direction as well, the distances from the substrate edge 27 need not be the same, only if the edge 28 of the gate insulation film 3 and the edge 29 of the first passivation film 8 are in a same positional relationship.

Using the TFT array substrate shown in FIG. 1 and FIG. 2, a photo-sensor, such as an x-ray imaging device, can be manufactured by a known method. Although not illustrated, an x-ray imaging device can be created by depositing a scintillator for converting an x-ray into visible light, made from CsI for example, on the fourth passivation film 18 shown in FIG. 1, and connecting a digital board having a low noise amplifier and an A/D converter, a driver board for driving TFT, and a read board for reading electric charges.

In the case of the TFT array substrate used for the photo-sensor according to the present embodiment, a drop in adhesion of the Si layer, constituting the photo-diode at the edge of the substrate when the Si layer is formed, can be prevented. Therefore the generation of foreign substances from the TFT array substrate can be suppressed, and a large photo-sensor can be implemented with very few defects.

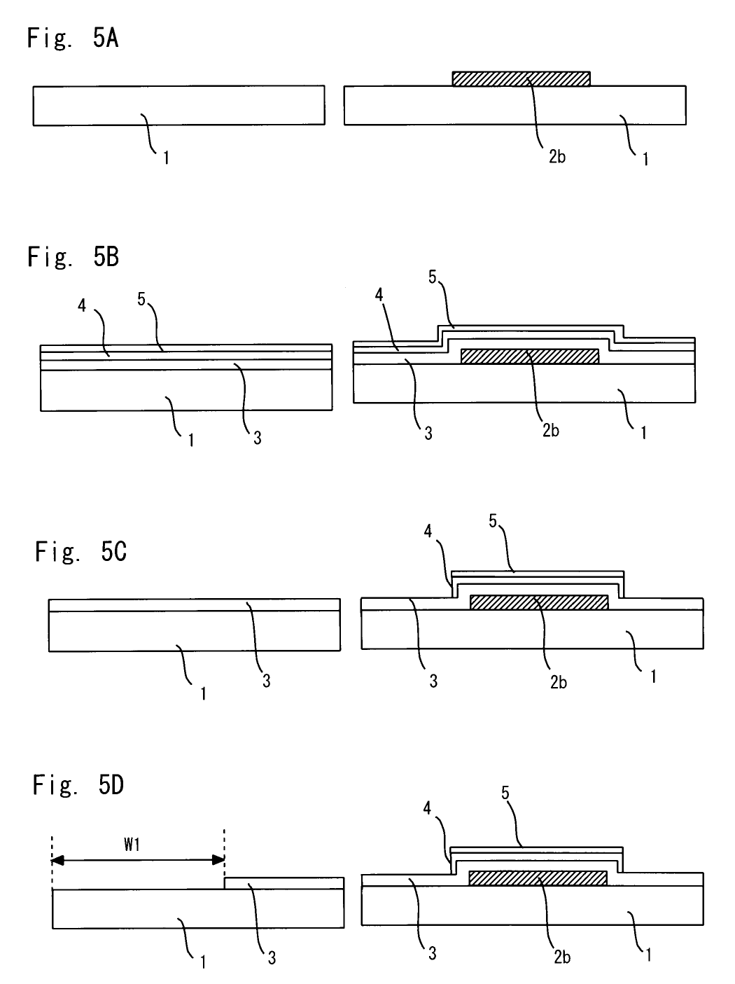

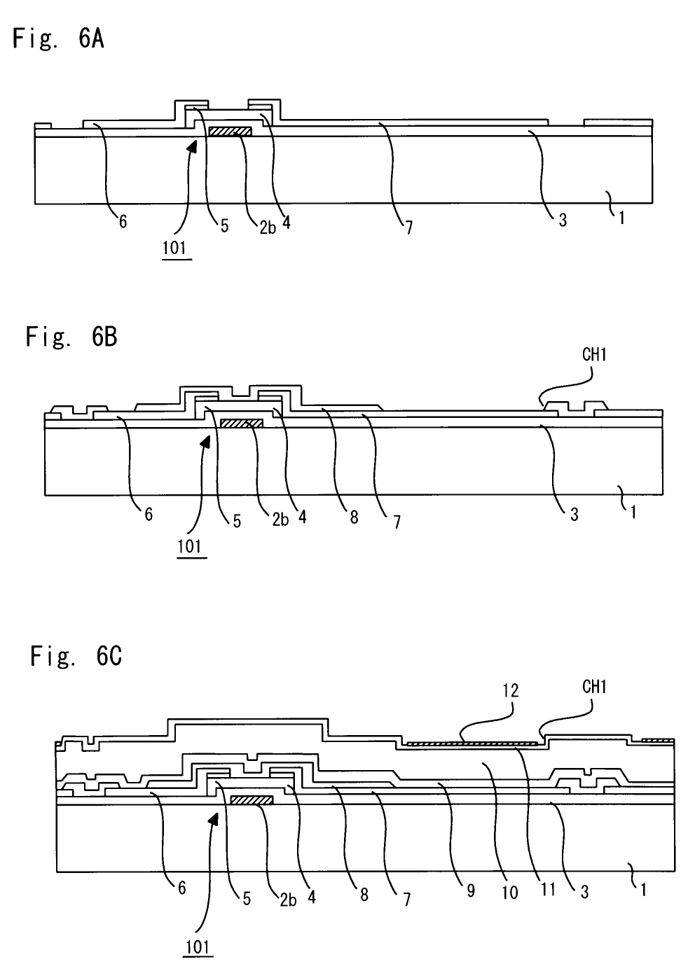

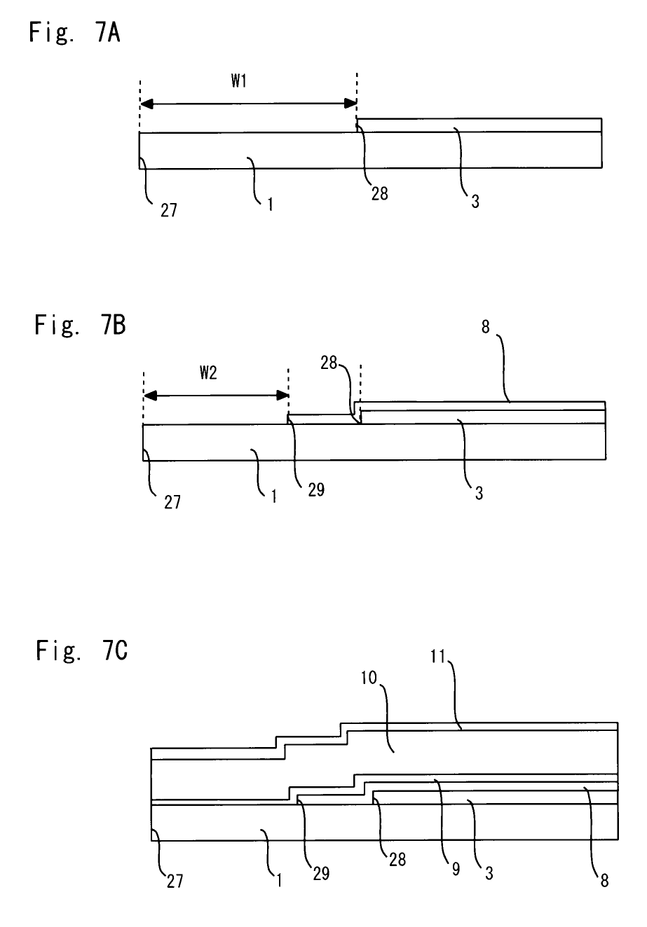

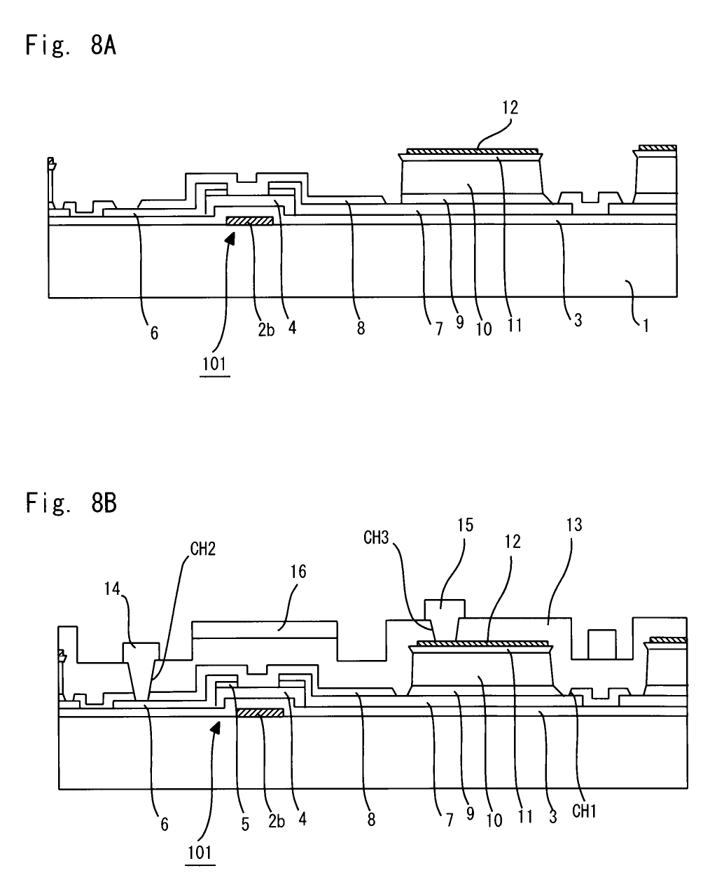

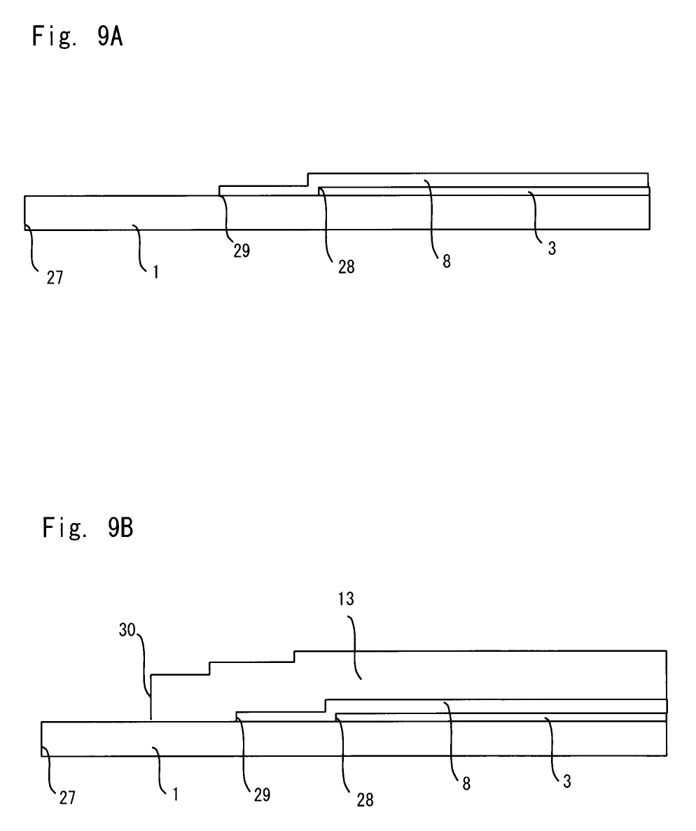

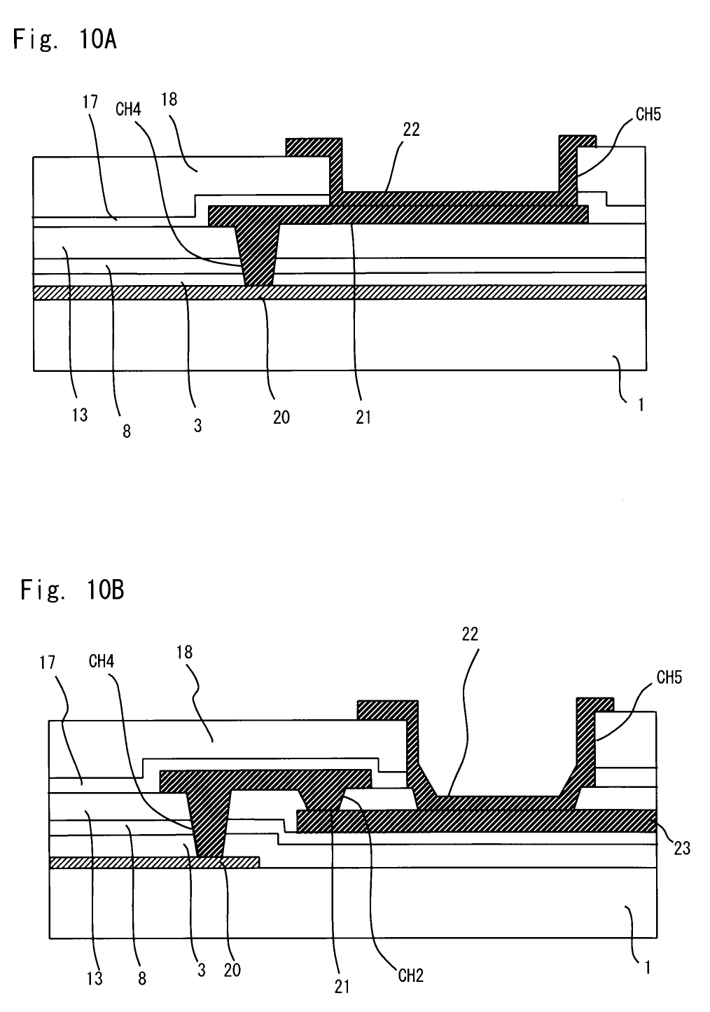

The manufacturing method for the TFT array substrate used for the photo-sensor according to the present embodiment will be described with reference to FIG. 5A to FIG. 5D, FIG. 6A to FIG. 6C, FIG. 7A to FIG. 7C, FIG. 8A, FIG. 8B, FIG. 9A and FIG. 9B. FIG. 5A to FIG. 5D, FIG. 6A to FIG. 6C, FIG. 7A to FIG. 7C, FIG. 8A, FIG. 8B, FIG. 9A and FIG. 9B are cross-sectional views of each step in location corresponding to FIG. 2 and FIG. 4. FIG. 6A to FIG. 6C and FIG. 7A to FIG. 7C show cross-sections at each location in the same steps respectively, and FIG. 8A, FIG. 8B, FIG. 9A and FIG. 9B show cross-sections at each location in the same steps respectively.

First a metal of which main component is Al is formed on the glass substrate 1 as a first conductive thin film. For example, the first conductive film is formed using an Al alloy containing Ni. That is, the first conductive film is formed using AlNiNd, for example, by a sputtering method. The film deposition conditions are a 0.2 to 0.5 Pa pressure and 1.0 to 2.5 kW DC power (0.17 to 0.43 W/cm² power density). The film deposition temperature is in a room temperature to 180° C. range.

The film thickness of the first conductive film is 150 to 300 nm. In order to suppress the reaction with developer, a nitrided AlNiNd layer may be formed on AlNiNd. AlNiSi or AlNiMg may be used instead of AlNiNd. If a same material is used for the data line 14 and the bias line 15, production efficiency can be improved. Cu or a Cu alloy, instead of Al, may be used as the low resistance metal material. In this case, the film can be formed by a sputtering method, just like the case of Al.

Then in the first photolithography step, resist is formed in the shape of a gate electrode. As FIG. 5A shows, in the etching step, the first conductive thin film is patterned using a mixed acid of phosphoric acid, nitric acid and acetic acid, for example. Thereby the gate line 2, including the gate electrode 2b, can be formed. If the sectional shape of the gate line 2 is tapered, defects in the film formation in later steps, such as disconnection, can be decreased. Here etching is performed by a mixed acid of phosphoric acid, nitric acid and acetic acid, as an example, but the etchant type is not limited to this. Dry etching may be used to form the gate line 2. In the present embodiment, the gate line 2 is not exposed when the photo-diode is formed. Therefore, for the gate line 2, a metal of which main component is Al or Cu, which is susceptible to damage, can be used. Since low resistant lines can be formed, a large sized photo-sensor can be used.

Then as FIG. 5B shows, the gate insulation film 3, a-Si:H (amorphous silicon to which hydrogen atoms have been added) semiconductor layer 4, and n+a-Si:H ohmic contact layer 5 are layered by a plasma CVD method. For example, the film thickness is 200 to 400 nm for the gate insulation film 3, 100 to 200 nm for the a-Si:H (amorphous silicon to which hydrogen atoms have been added) semiconductor layer 4, and 20 to 50 nm for the n+a-Si:H ohmic contact layer 5. Since a high electric charge reading efficiency is demanded for the photo-sensor, transistors having high drive capability are required. Therefore the a-Si:H semiconductor layer 4 may be deposited in two steps, so as to improve performance of the transistor. In this case, a film deposition condition is a depo rate of 5 to 20 nm/min (50 to 200 Å/min) for the first layer. By this low depo rate, a good quality film is formed. Then a 30 nm/min (300 Å/min) or higher depot rate is used for the remaining layers. The gate insulation film 3, a-Si:H semiconductor layer 4, and the n+a-Si:H ohmic contact layer 5 are formed under a film deposition temperature of 250 to 350° C.

Then in the second photolithography step, resist is formed in a channel shape. Then in the etching step, the semiconductor layer 4 and the ohmic contact layer 5 are patterned to form an island, as FIG. 5C shows. In the semiconductor layer 4 formed in an island shape, the source region, drain region and channel region are formed. During etching, plasma is generated using a mixed gas of SF₆ and HCl, for example. If the sectional shape of the channel is tapered, defects in film formation in later steps, such as disconnection, can be decreased. Here etching gas is a mixed gas of SF₆ and HCl, as an example, but the gas type used for etching is not limited to this.

Then in the third photography step, a pattern which opens only the edge of the substrate (not illustrated) is formed. The peripheral area of the gate insulation film 3 is removed all around the substrate, as FIG. 5D shows. In the peripheral area 103, the gate insulation film 3 is removed until the surface of the substrate 1 is exposed. In the etching, patterning is performed using plasma of a mixed gas of CF₄ and O₂, for example. Here the etching gas is a mix of CF₄ and O₂, but the etching gas is not limited to this.

Then the second conductive thin film is formed. The second conductive thin film is formed by depositing high melting point metal film, such as Cr, using a sputtering method, for example. The film thickness of the second conductive thin film is 50 to 300 nm.

Then in the fourth photolithography step, a resist (not illustrated), corresponding to the source electrode and drain electrode, is formed. As FIG. 6A and FIG. 7A show, the second conductive thin film is patterned in the etching step. Thereby the source electrode 6 and the drain electrode 7 are formed. In the etching step, a mixed acid of cerium nitrate ammonium and nitric acid, for example, is used. Then the ohmic contact layer 5 is etched using the formed electrode as a mask. Here dry etching is performed using a mixed gas of SF₆ and HCl, for example. Thereby a thin film transistor is formed. In the steps thus far, three masks are used, but the number of masks may be decreased by using a gray tone mask. For example, a gray tone mask is used in the second and third photolithography steps, where a silicon island is formed and the source electrode 6, drain electrode 7 and ohmic contact layer 5 are formed. As a result, the silicon island, source electrode 6, drain electrode 7 and ohmic contact layer 5 can be formed by a step using one mask.

For the etchant to form the source electrode 6 and the drain electrode 7, a mixed acid of cerium nitrate ammonium and nitric acid is used, but the etchant is not limited to this. For the etching gas to form the ohmic contact layer 5, a mixed acid of SF₆ and HCl is used, but the etching gas is not limited to this. Also in the present embodiment, Cr is used for the second conductive thin film, but a material other than Cr may be used for the second conductor thin film. In this case, it is preferable to use a metal material which can have ohmic contact with Si. After this step, in order to improve the characteristics of the thin film transistor, plasma processing may be performed before forming the passivation film 8. By performing plasma processing using hydrogen gas, the surface of the back channel side, that is, the surface of the semiconductor layer 4, can be roughened. Thereby TFT 101 is formed.

Then the first passivation film 8 is formed by such a method as plasma CVD, as shown in FIG. 6B and FIG. 7B. In the fifth photolithography step, the contact hole CH1 is formed using a resist (not illustrated). By this contact hole CH1, the drain electrode 7 and the amorphous silicon film 9, in which P (phosphorus) has been doped, can be contacted. For example, the contact hole CH1 is formed by etching and patterning the first passivation film 8. For this etching, plasma of a mixed gas of CF₄ and O₂ can be used. The first passivation film 8 in the peripheral area 103 of the substrate 1 is removed all around the substrate. The edge 29 of the first passivation film 8 is formed outside the edge 28 of the gate insulation film 3. In other words, width W1 from the edge of the substrate 1 to the edge 28 of the gate insulation film 3 is greater than width W2 from the edge of the substrate 1 to the edge 29 of the first passivation film 8. For the first passivation film 8, silicon dioxide (SiO₂) film having a low dielectric constant is formed to be a 200 to 400 nm film thickness. The film deposition conditions of silicon dioxide film are an SiH₄ flow rate of 1.69 to 8.45×10⁻² Pa·m³/s (10 to 50 sccm), an N₂O flow rate of 3.38 to 8.45×10⁻¹ Pa·m³/s (200 to 500 sccm), a film deposition pressure of 50 Pa, and an RF power of 50 to 200 W (0.015 to 0.67 W/cm² power density). The film deposition temperature is 200 to 300° C.

A mixed gas of CF₄ and O₂ is used for the etching gas, but the type of etching gas is not limited to this. Also silicon dioxide is used for the first passivation film 8, but the first passivation film 8 is not limited to this. The first passivation film 8 may be SiN or SiON. For the first passivation film 8, a layered film of SiN (lower layer) and SiO₂ (upper layer) may be used. Also for the first passivation film 8, a layered film of SiON (lower layer) and SiO₂ (upper layer) may be used. In this case, the first passivation film 8 is formed using the above gas to which hydrogen, nitrogen and NH3 are added. In the fourth photolithography step, the opening edge of the contact hole CH1 is formed by a mask which is disposed outside the edge of the area where the drain electrode 7 and the photo-diode 100 are connected.

Then the amorphous silicon film 9, amorphous silicon film 10 and amorphous silicon film 11 are formed by a plasma CVD method. In the amorphous silicon film 9, P (phosphorus), for forming the photo-diode 100, is doped. The amorphous silicon film 10 is intrinsic. In the amorphous silicon film 11, B (boron) is doped. The amorphous silicon films 9, 10 and 11 are sequentially formed in a same deposition chamber, while maintaining the vacuum state. Each film thickness of the layered silicon film is 5 to 60 nm for the P (phosphorus)-doped amorphous silicon film 9, 0.5 to 2.0 μm for the intrinsic amorphous silicon film 10, and 10 to 80 nm for the B (boron)-doped amorphous silicon 11. For the intrinsic amorphous silicon film 10, the SiH₄ flow rate is 1.69 to 3.38×10⁻¹ Pa·m³/s (100 to 200 sccm), the H₂ flow rate is 1.69 to 5.07×10⁻¹ Pa·m³/s (100 to 300 sccm), the film deposition pressure is 100 to 300 Pa, the RF power is 30 to 150 W (0.01 to 0.05 W/cm² power density), and the film deposition temperature is 200 to 300° C. P (phosphorus) or B (boron)-doped silicon films are formed by a film deposition gas where 0.2 to 1.0% PH₃ or B₂H₆ is mixed with the above mentioned gas of the film deposition conditions respectively.

The B (boron)-doped amorphous silicon film 11 may be formed by an ion shower doping method, or by an ion implantation method. For example, B (boron) is implanted into the top layer of the intrinsic amorphous silicon film 10 to form the amorphous silicon film 11. If B-doped amorphous silicon film 11 is formed by ion implantation, a 5 to 40 nm thick SiO₂ film may be formed on the surface of the intrinsic amorphous silicon film 10 prior to implanting B. This is for decreasing the damage caused when B is implanted. In this case, the SiO₂ film may be removed by BHF, for example, after ion implantation.

Then a non-crystal transparent conductive film is formed by a sputtering method using one of the targets: IZO, ITZO and ITSO. The film deposition conditions are a pressure of 0.3 to 0.6 Pa, DC power of 3 to 10 kW (0.65 to 2.3 W/cm² power density), an Ar flow rate of 8.45 to 25.4×10⁻² Pa·m³/s (50 to 150 sccm), and an oxygen flow rate of 1.69 to 3.38×10⁻³ Pa·m³/s (1 to 2 sccm). The film deposition temperature is from room temperature to about 180° C. The non-crystal transparent conductive film is formed based on the above conditions. After the non-crystal transparent conductive film is formed, the resist (not illustrated) is formed in the sixth photolithography step. Then as FIG. 6C and FIG. 7C show, the transparent electrode 12 is formed by performing etching using oxalic acid, for example, and patterning. The oxalic acid is used here for the etchant, but the etchant is not limited to this. In the present embodiment, the film containing IZO, ITZO or ITSO is used for the transparent electrode 12. By this, a non-crystal state transparent conductive film, which hardly contains micro-crystal grains, is formed on the B (boron)-doped amorphous silicon film 11. This means that an etching residue is not generated. For the transparent electrode 12, a single layer film, in which the above materials are mixed, may be used, or a structure in which films made from the respective materials may be layered. A film in which the respective materials are mixed may be layered.

Then the resist pattern is formed in the seventh photolithography step. The resist pattern is one size bigger than the pattern of the transparent electrode 12, and comes inside the edge of the opening of the contact hole CH1. Then as FIG. 8A and FIG. 9A show, the three amorphous silicon layers, that is, the P (phosphorus)-doped amorphous silicon film 9, intrinsic amorphous silicon film 10 and B (boron)-doped amorphous silicon film 11 are patterned using the plasma of a mixed gas of SF₆ and HCl. As FIG. 9A shows, in the peripheral area 103 of the substrate 1, the amorphous silicon films 9, 10 and 11 are removed, and the first passivation film 8 is exposed. The gate insulation film 3, which is covered by the first passivation film 8, is not exposed. For the etching gas, the mixed gas of SF₆ and HCl is used, but the etching gas is not limited to this. Thereby the photo-diode having the three-layer structure is formed. The three-layer photo-diode comprised of the P (phosphorus)-doped amorphous silicon film 9, intrinsic amorphous silicon film 10 and B (boron)-doped amorphous silicon film 11 is formed inside the edge of the opening of the contact hole CH1. Therefore the photo-diode is formed inside the pattern edge of the drain electrode 7.

Then the second passivation film 13 for protecting the photo-diode is formed. Then in the eighth photolithography step, a resist pattern (not illustrated) corresponding to the contact holes CH2 and CH3 is formed. The contact hole CH2 is formed to connect the source electrode 6 and the data line 14, and the contact hole CH3 is formed to connect the transparent electrode 12 of the photo-diode and the bias line 15. Then the contact holes are patterned using a mixed gas of CF₄ and Ar. At this time, the contact hole CH4 and the contact hole CH6, for connecting the edge of the gate line 2 and the conductive pattern 21, may be opened simultaneously. In order to decrease the load capacity applied to the data line 14 and the bias line 15, the silicon oxide film having a low dielectric constant is deposited to be a 0.5 to 1.5 μm thickness as the second passivation film 13. The film deposition conditions of the silicon oxide film are the SiH₄ flow rate of 1.69 to 8.45×10⁻² Pa·m³/s (10 to 50 sccm), N₂O flow rate of 3.38 to 8.45×10⁻¹ Pa·m³/s (200 to 500 sccm), film deposition pressure of 50 Pa and RF power of 50 to 200 W (0.015 to 0.67 W/cm² power density). The film deposition temperature is 200 to 300° C. The silicon oxide film is used for the material of the second passivation film 13, but the material is not limited to this.

The second passivation film 13 may be SiN, for example. When the opening of the contact hole is created, it is preferable to process so that the cross-section thereof is tapered. Thereby coverage of the top layer is improved, and disconnection can be decreased. According to the present embodiment, the contact holes CH2 and CH3 are opened after depositing the second passivation film 13, but the manufacturing method is not limited to this. For example, the contact holes CH2 and CH3, or locations corresponding to contact holes CH4 and CH6, may be opened simultaneously when the contact hole CH1 is opened in advance. In this case, the first passivation film 8 is removed, so the etching time for opening after the second passivation film 13 is deposited can be decreased.

Then the third conductive thin film is deposited in order to form the data line 14, bias line 15 and light shielding layer 16. For the third conductive thin film, a material of which resistance is low, heat resistance is good and contact characteristic with the transparent conductive film is good is used. Therefore an Al alloy containing Ni is used to form the third conductive thin film. For example, AlNiNd is deposited to be a 0.5 to 1.5 μm film thickness as the third conductive thin film. The data line 14 and the bias line 15 may be a single layer of AlNiNd. The data line 14 and the bias line 15 may also be layers of AlNiNd and a high melting point metal, such as Mo, an Mo alloy or Cr. In order to suppress a reaction with the developer, a nitrided AlNiNd may be formed on AlNiNd. For example, an Mo alloy is deposited for the substrate, and AlNiNd is continuously deposited thereon, by a sputtering method. The film deposition conditions are the pressure of 0.2 to 0.5 Pa, and DC power of 1.0 to 2.5 kW (0.17 to 0.43 W/cm² power density). The film deposition temperature is from room temperature to about a 180° C. range.

Then as FIG. 8B and FIG. 9B show, a resist corresponding to the data line 14, bias line 15 and light shielding layer 16 is formed in the ninth photolithography step. In the case of a layered film of AlNiNd and Mo, patterning is performed using a mixed acid of phosphoric acid, nitric acid and acetic acid, for example. For the etchant, a mixed acid of phosphoric acid, nitric acid and acetic acid is used, but the type of etchant is not limited to this. Here the data line 14 is connected with the source electrode 6 via CH2. The bias line 15 is connected with the transparent electrode 12 via CH3. For the bias line 15, an Al alloy containing Ni or a high melting point metal is used for the bottom layer, as mentioned above. Therefore the contact resistance with the transparent electrode 12, which is the lower layer, is low, and good connection is implemented.

Then the third passivation film 17 and the fourth passivation film 18 are formed to protect the data line 14 and bias line 15. For example, SiN is used for the third passivation film 17, and a leveling film is used for the fourth passivation film 18.

In the tenth photolithography step, the contact holes CH5 and CH7, for connecting with terminals, are formed using a resist. Then patterning is performed using plasma of a mixed gas of CF₄ and O₂. For the etching gas, the mixed gas of CF₄ and O₂ is used, but the etching gas to be used is not limited to this. For the fourth passivation film 18, a leveling film having photosensitivity is used. The patterning of the fourth passivation film 18 in the tenth photolithography step may be performed by exposure and development processing.

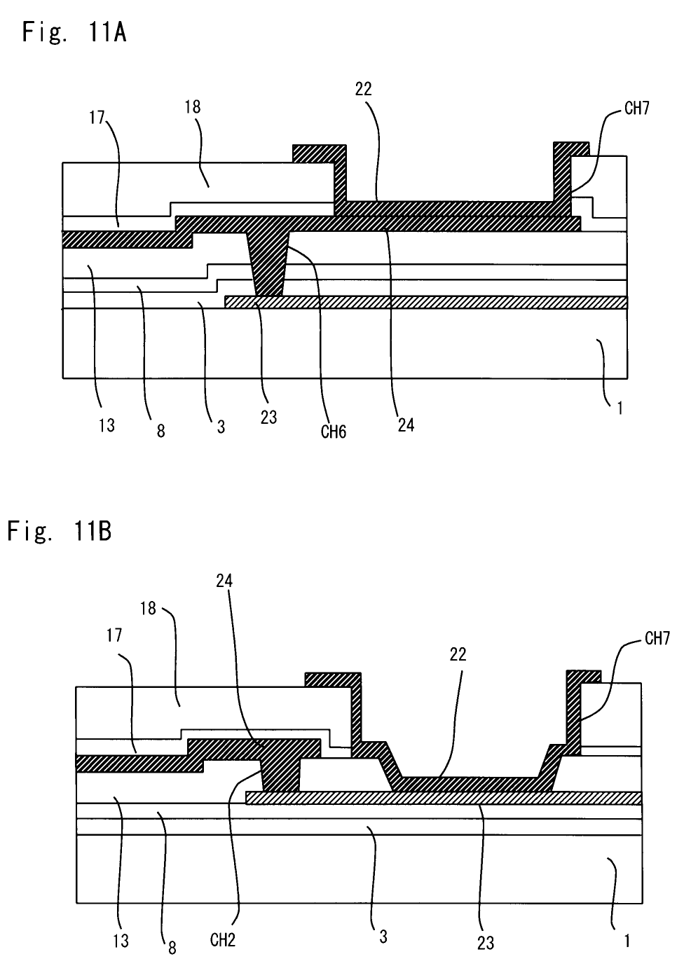

Then the conductive film to be the terminal lead electrode 22 is formed. In order to insure reliability, the transparent conductive film such as the amorphous ITO is formed for the electrode. Then the terminal shape resist is formed in the eleventh photolithography step. For example, the terminal lead electrode 22 is formed by etching using oxalic acid. The terminal lead electrode 22 is formed in the terminal area 104 shown in FIG. 3. The terminal lead electrode 22 is a lead electrode for connecting such lines as the gate line 2, data line 14 and bias line 15 with the outside in the terminal area 104. Then ITO is crystallized by annealing. Here the terminal lead electrodes 22 are connected with the conductive pattern 21 and the edge 24 of the line via the contact holes CH5 and CH7, as shown in FIG. 10A, FIG. 10B, FIG. 11A and FIG. 11B.

FIG. 10A is a cross-sectional view of the terminal area 104 of the glass substrate 1. As FIG. 10A shows, the contact hole CH4 is formed so as to penetrate the gate insulation film 3, first passivation film 8 and second passivation film 13. The conductive pattern 21 is formed on the second passivation film 13. This conductive pattern 21 is formed on the same layer as the data line 14 and the bias line 15. The conductive pattern 21 is connected to the edge 20 of the line via the contact hole CH4. The contact hole CH5 is formed so as to penetrate the third passivation film 17 and the fourth passivation film 18. The terminal lead electrode 22 is formed so as to extend from inside the contact hole CH5 to the surface of the fourth passivation film 18. The terminal lead electrode 22 is formed on the bottom face and side face of the contact hole CH5. The terminal lead electrode 22 is connected with the conductive pattern 21 via the contact hole CH5. In other words, the terminal lead electrode 22 is connected with the edge 20 of the line via the conductive pattern 21. This terminal lead electrode 22 is formed in the terminal area 104, and becomes a lead terminal of the gate line 2, for example.

For lines other than the gate line 2, such as data line 14 and bias line 15, the conductive layer formed as a line is connected to the lead electrode 22 formed on the substrate surface via the contact hole. The terminal lead electrode 22 is formed in the terminal area 104, and becomes a lead electrode for connecting the respective line with the outside.

FIG. 10B is another cross-sectional view of the terminal area 104 of the glass substrate 1. As FIG. 10B shows, the contact hole CH4 is formed so as to penetrate the gate insulation film 3, the first passivation film 8 and the second passivation film 13. The conductive pattern 21 is formed on the second passivation film 13. The conductive pattern 21 is formed on the same layer as the data line 14 and the bias line 15. The conductive pattern 21 is connected to the edge 20 of the line via the contact hole CH4. The short ring line 23 is formed on the first passivation film 8. The short ring line 23 is disposed closer to the substrate edge than the edge 20 of the line. The short ring line 23 is formed in the terminal area 104, for example. The contact hole CH2 is formed in the second passivation film 13. The conductive pattern 21 is connected to the short ring line 23 via the contact hole CH2.

The short ring line 23 is formed on the same layer as the transparent electrode 12. In other words, the short ring line 23 is connected to the edge 20 of the line via the conductive pattern 21. The contact hole CH5 is formed so as to penetrate the second passivation film 13, third passivation film 17 and fourth passivation film 18. The terminal lead electrode 22 is formed so as to extend from inside the contact hole CH5 to the surface of the fourth passivation film 18. The terminal lead electrode 22 is formed on the bottom face and side face of the contact hole CH5. The terminal lead electrode 22 is connected to the short ring line 23 via the contact hole CH5. In other words, the terminal lead electrode 22 is connected to the edge 20 of the line via the short ring line 23 and the conductive pattern 21. The edge 20 of the line shown in FIG. 10B can be the edge of the gate line 2, for example. The short ring line 23 is connected, for example, to an external protective circuit, which is not illustrated. The short ring line 23 is formed to protect the photo-sensor by shorting the connected line when over current flows through the line in the manufacturing step of the photo-sensor, for example.

FIG. 11A is a cross-sectional view of the terminals of the data line 14 and bias line 15 in the terminal area 104 of the glass substrate 1. As FIG. 11A shows, the short ring line 23 is formed on the glass substrate 1. This short ring line 23 is formed on the same layer as the gate line 2. The contact hole CH6 is formed so as to penetrate the gate insulation film 3, first passivation film 8 and second passivation film 13. The edge 24 of the line is formed on the second passivation film 13. The edge 24 of the line is connected to the short ring line 23 via the contact hole CH6. The contact hole CH7 is formed so as to penetrate the third passivation film 17 and the fourth passivation film 18. The terminal lead electrode 22 is formed so as to extend from inside the contact hole CH7 to the surface of the fourth passivation film 18. The terminal lead electrode 22 is formed on the bottom face and side face of the contact hole CH7. The terminal lead electrode 22 is connected to the edge 24 of the line via the contact hole CH7. In other words, the terminal lead electrode 22 is connected to the short ring line 23 via the edge 24 of the line. For example, the edge 24 of the line can be the edge of the data line 14 or bias line 15. The terminal lead electrode 22 can also be a lead terminal of the short ring line 23 connected to the data line 14 or bias line 15, for example.

FIG. 11B is another cross-sectional view of the terminal disposed in the data line 14 or bias line 15 in the terminal area 104 of the glass substrate 1. In FIG. 11B, a short ring line 23 is formed in a conductive layer which is different from FIG. 11A. As FIG. 11B shows, the short ring line 23 is formed on the first passivation film 8. This short ring line 23 is formed on the same layer as the transparent electrode 12. The contact hole CH2 is formed in the second passivation film 13. The edge 24 of the line is formed on the second passivation film 13. The edge 24 of the line is connected to the short ring line 23 via the contact hole CH2. The short ring line 23 is formed closer to the substrate edge than the edge 24 of the line.

The contact hole CH7 is formed so as to penetrate the second passivation film 13, third passivation film 17 and fourth passivation film 18. The terminal lead electrode 22 is formed so as to extend from inside the contact hole CH7 to the surface of the fourth passivation film 18. The terminal lead electrode 22 is formed on the bottom face and side face of the contact hole CH7. The terminal lead electrode 22 is connected to the short ring line 23 via the contact hole CH7. In other words, the terminal lead electrode 22 is connected to the edge 24 of the line via the short ring line 23. The edge 24 of the line can be the edge of the data line 14 or bias line 15, for example.

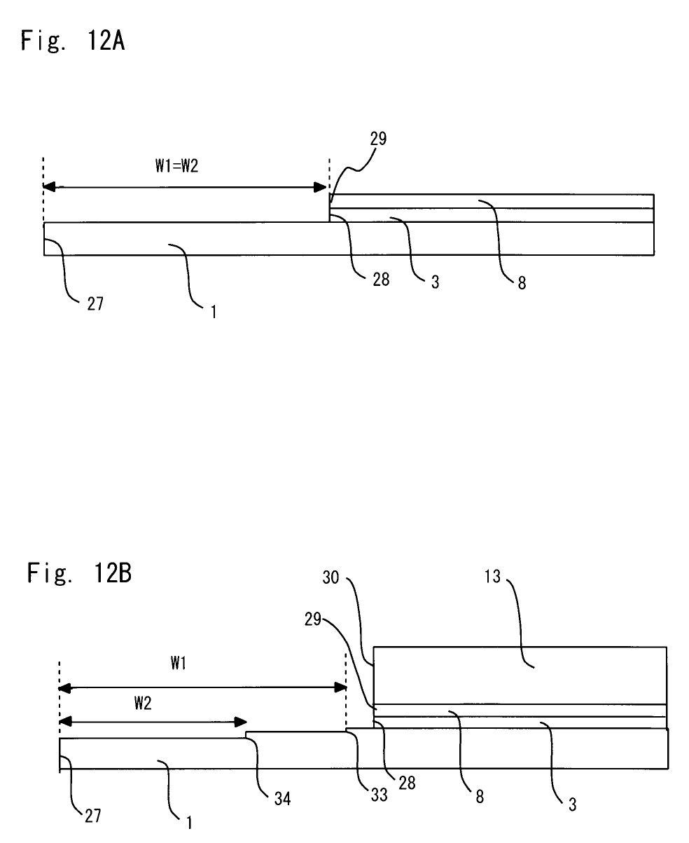

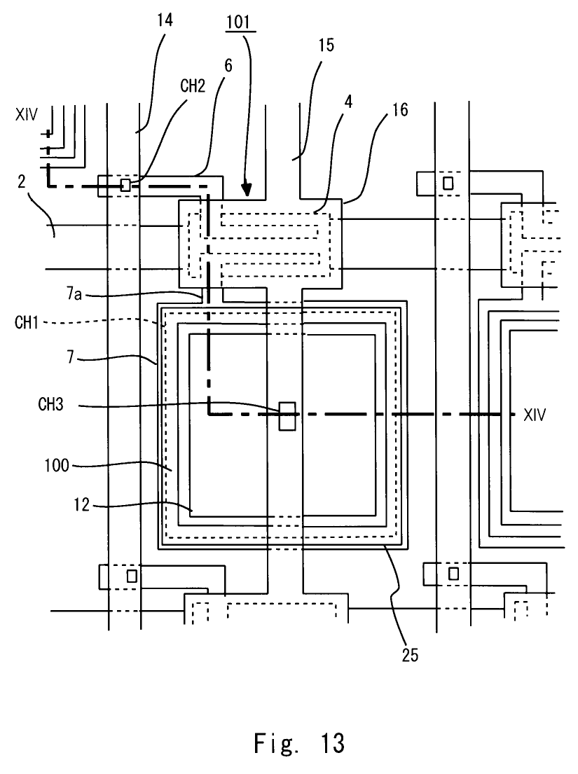

In the description of the present embodiment, the gate insulation film 3 in the periphery of the substrate is removed using the pattern in the third photolithography step, but the gate insulation film 3 in the periphery may be removed after forming the source electrode 6 and the drain electrode 7. For example, after the ohmic contact layer 5 is formed, the ohmic contact layer 5, semiconductor layer 4 and gate insulation film 3 at the periphery may be removed. For the mask pattern for performing patterning to open the contact hole CH1 in the fifth photolithography step, a mask pattern of which substrate periphery is opened is used. And in the step of forming the contact hole CH1, the first passivation film 8 and the gate insulation film 3 are simultaneously removed using this mask pattern to create the shape in FIG. 12A. According to this method, the gate insulation film 3 and the first passivation film 8 in the peripheral area 103 can be etched in the fifth photolithography step, so the third photolithography step can be omitted. If the first passivation film 8 and the gate insulation film 3 are simultaneously removed, an etching condition which minimizes dry etch damage on the drain electrode 7 is desirable.

In FIG. 10B and FIG. 11B, the short ring line 23 is disposed between the first passivation film 8 and the second passivation film 13, but the short ring line 23 may be formed on another layer. For example, the short ring line 23 may be formed on the layer between the gate insulation film 3 and the first passivation film 8. In this case, the contact hole to penetrate the first passivation film 8 is formed on this layer. For certain the short ring line 23 may be on a layer which is different from the transparent electrode 12.

In the description of the present embodiment, the edge 30 of the second passivation film 13 is disposed closer to the substrate edge than the first passivation film 8, but in the following case, the edge 30 of the second passivation film 13 is roughly at the same position as the edge 28 of the gate insulation film 3 and the edge 29 of the first passivation film 8, as shown in FIG. 12B. In other words, if a part of the first passivation film 8 and a part of the gate insulation film 3 at the substrate edge are simultaneously etched when the contact holes CH2, CH3, CH4 and CH6 are formed, the edges 28 and 29 of the etched films have roughly the same shape as the edge 30 of the second passivation film 13. And as shown in FIG. 12B, the trace 33 of the first passivation film 8 and the trace 34 of the gate insulation film 3 remain on the glass substrate 1, at the positions of widths W1 and W2 from the substrate edge.

In the manufacturing steps of the conventional photo-sensor, the amorphous silicon layers 9, 10 and 11 are deposited on the gate insulation film 3 and first passivation film 8, all the way to the edge of the substrate. Therefore at the edge of the substrate 1, the amorphous silicon films 9, 10 and 11, having a thick film thickness, are formed on the layers of the gate insulation film 3 and the first passivation film 8. This means that adhesion of the gate insulation film 3 and the amorphous silicon films 9, 10 and 11 is weakened as the film thickness of the amorphous silicon increases to increase the output of the photo-diode. Hence the amorphous silicon films peel off at the edge of the substrate 1. Whereas according to the present embodiment, the gate insulation film 3 is removed at the peripheral area 103 of the substrate 1, whereby adhesion of the substrate 1 and the amorphous silicon films 9, 10 and 11 is improved. Also the first passivation film 8 is formed so as to cover the edge 28 of the gate insulation film 3, so the amorphous silicon films can easily climb over the step difference at the substrate edge. As a result, adhesion of the amorphous silicon at the substrate edge can be improved, and reliability of the photo-sensor can be increased.

### Embodiment 2

According to Embodiment 1, when the contact hole CH1, for connecting the drain electrode 7 to be the lower electrode of the photo-diode 100 and the amorphous silicon film 9, is formed, the components of the etching gas may generate polymers, which reattach the drain electrode 7, depending on the conditions of the etching. In such a state, adhesion of the amorphous silicon film and the drain electrode 7 worsens when the P (phosphorus)-doped amorphous silicon film 9, intrinsic amorphous silicon film 10 and B (boron)-doped amorphous silicon film 11 constituting the photo-diode are formed. This may result in peeling of the amorphous silicon films.

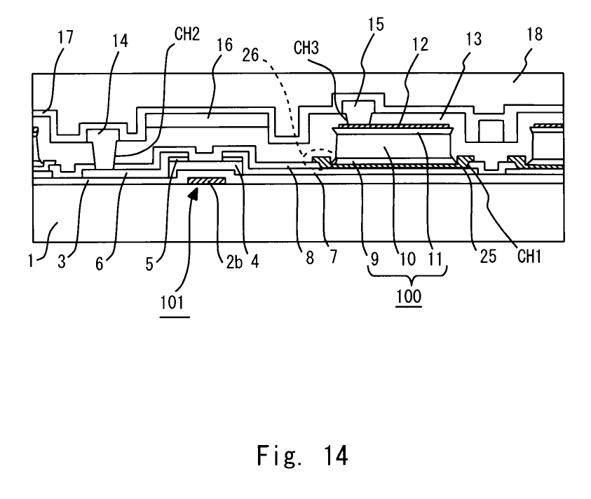

In the present embodiment, a configuration to prevent peeling of the amorphous film at the periphery of the photo-diode 100 and TFT array substrate is described. This configuration will now be described based on FIG. 13 and FIG. 14. FIG. 13 is a plan view depicting the TFT array substrate used for the photo-sensor according to the present embodiment. FIG. 14 is a cross-sectional view sectioned at XIV-XIV in FIG. 13. According to Embodiment 2, a lower electrode 25 is formed below the photo-diode 100, as shown in FIG. 13 and FIG. 14. The lower electrode 25 is formed so as to cover a contact hole CH1. The lower electrode 25 extends from inside the contact hole CH1 to the upper surface of the first passivation film 8. A photo-diode 100 is formed on the lower electrode 25, and is connected with the lower electrode 25. The photo-diode 100 is enclosed in the contact hole CH1. The photo-diode 100 is disposed so as to not cross-over the area near the edge of the opening of the contact hole CH1 (broken line area 26 in FIG. 14). Therefore just like Embodiment 1, peeling of the amorphous silicon film at the periphery of the substrate can be prevented, and also peeling of the amorphous silicon film within a TFT array pattern can be prevented.

Now the manufacturing method will be described. The manufacturing steps up to forming the contact hole CH1 by the fifth photolithography step are the same as the manufacturing method of Embodiment 1, so description thereof is omitted. According to Embodiment 2, a fourth conductive thin film to be the lower electrode 25 of the photo-diode 100 is formed after the contact hole CH1 is formed. A sputtering method, for example, can be used to form the fourth conductive film. The fourth conductive thin film is formed by depositing a high melting point metal film, such as Cr.

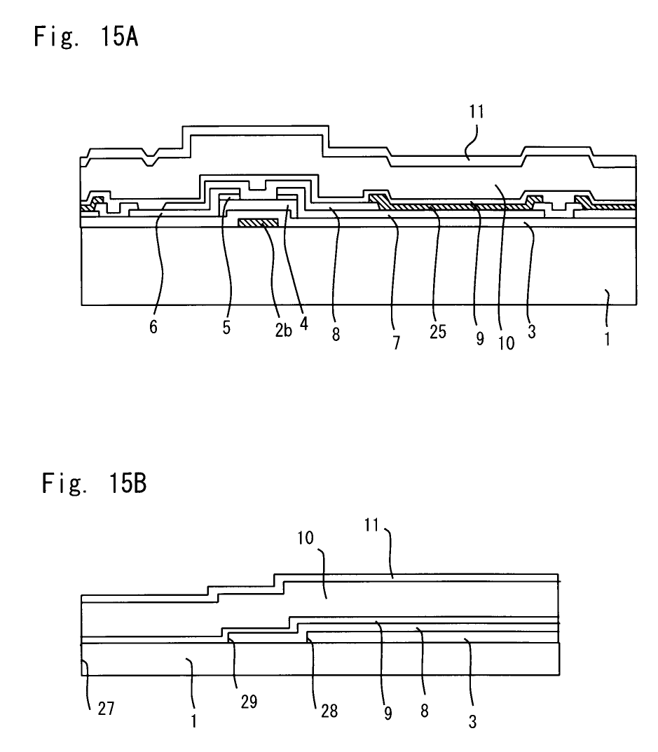

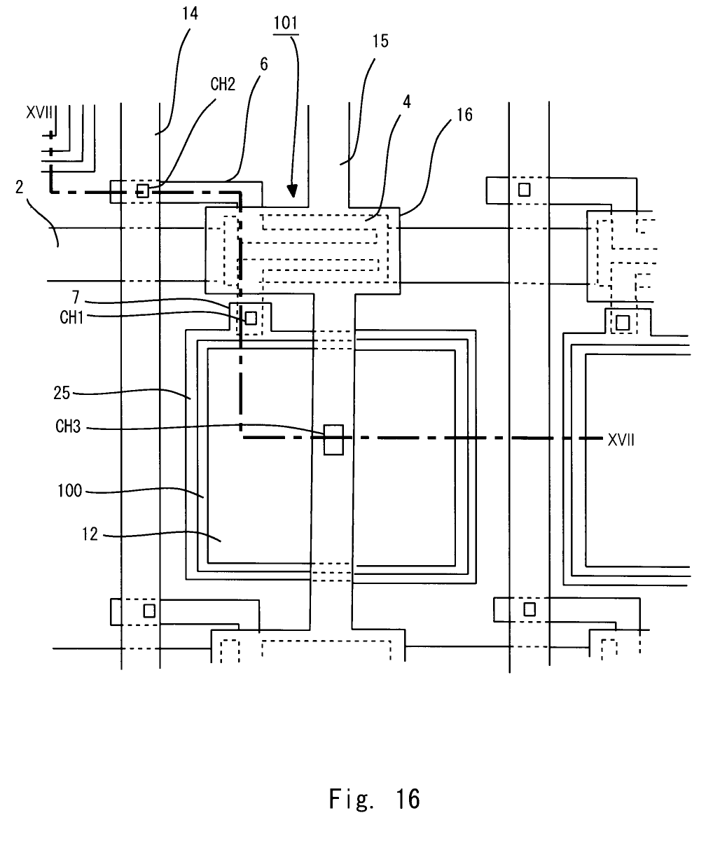

In the manufacturing method of Embodiment 2, one more photolithography step is added between the fifth photolithography step and the sixth photolithography step of Embodiment 1. As FIG. 15A and FIG. 15B show, the lower electrode 25 of the photo-diode is formed so as to cover the contact hole CH1 in this added photolithography step. Then the P (phosphorus)-doped amorphous silicon film 9, intrinsic amorphous silicon film 10 and B (boron)-doped amorphous silicon film 11 are deposited. The lower electrode 25 is formed after the contact hole CH1 is formed, and surface contamination hardly remains on the surface of the lower electrode 25. Therefore the adhesion of the lower electrode 25 and the amorphous silicon layered film improves, and peeling of films can be prevented. The interface between the drain electrode 7 and the lower electrode 25 may be contaminated with remaining polymers, due to etching gas, but the increase in the contact resistance between the drain electrode 7 and the lower electrode 25 is very little compared with the contact resistance with the photo-diode, so this is not a problem.

The manufacturing method after forming the amorphous silicon layered film, which is the same as Embodiment 1, is omitted. As mentioned above, Embodiment 2 is characterized in that, the photo-diode 100 does not cross-over the area where the lower electrode 25 covers the first passivation film 8 (broken line area 26 in FIG. 14) near the edge of the opening of the contact hole CH1, where Therefore just like Embodiment 1, the amorphous silicon layered film constituting the photo-diode 100 has no area to climb over the step difference. Therefore a good photo-diode 100 with very little leak current can be formed. Also the lower electrode 25 is formed, and the photo-diode 100 is formed thereon. Thereby peeling of the amorphous silicon film due to polymers which attach when the contact hole CH1 is opened can be prevented.

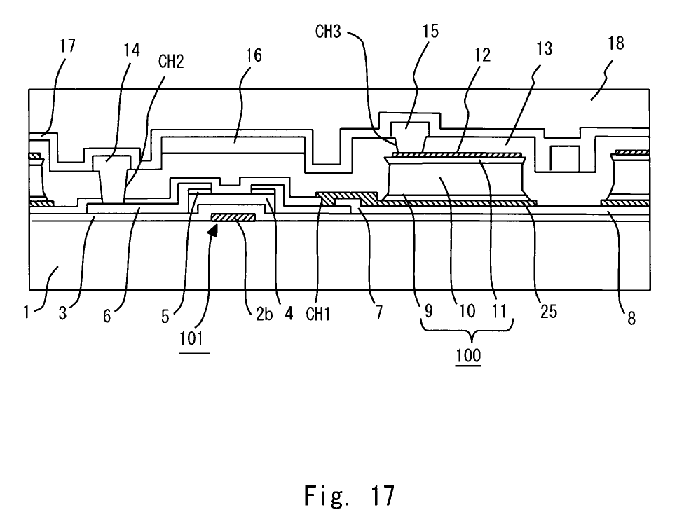

In the description of the present embodiment, the photo-diode 100 is enclosed in the lower electrode 25, and the photo-diode 100 is disposed inside the edge of the opening of the contact hole CH1. However various margins in the photolithography step must be considered during design, in order to dispose the photo-diode 100, as mentioned above. In other words, design must be performed considered at least the two types of alignment margins, that is, the alignment margin between the contact hole CH1 and the drain electrode 7, and the alignment margin between the contact hole CH1 and the photo-diode, and the three types of finish dispersion of the contact hole CH1, drain electrode 7 and photo-diode. If the photo-diode 100 is disposed considering these conditions, the aperture ratio of the photo-diode may drop. A variant form of Embodiment 2, which does not drop the aperture ratio, will now be described with reference to FIG. 16 and FIG. 17. FIG. 16 is a plan view of the TFT array substrate used for the photo-sensor according to the present embodiment. FIG. 17 is a cross-sectional view sectioned at XVII-XVII in FIG. 16.

For the manufacturing method, which is the same as Embodiment 2 except for a part of the mask dimensions, description is omitted. In other words, only the mask dimensions, when the drain electrode 7 is formed and when the opening of the contact hole CH1 and the lower electrode 25 are formed, is different from the above mentioned manufacturing method. As FIG. 16 shows, according to the variant form, the edge of the opening of the contact hole CH1 of the drain electrode 7 and the lower electrode 25 is constructed such that the amorphous silicon layered film constituting the photo-diode 100 does not climb over the opening edge, just like Embodiment 2. The variant form is characterized in that the amorphous silicon layered film constituting the photo-diode 100 is formed outside the contact hole CH1. The lower electrode 25 extends from inside the contact hole CH1 to the surface of the first passivation film 8.

The photo-diode 100 is formed outside the contact hole CH1 on the lower electrode 25 formed on the first passivation film 8. Thus according to the variant form, the photo-diode 100 does not climb over the step difference of the edge of the opening of the contact hole CH1, and is formed on the uniform underlayer film outside the contact hole CH1. Therefore the phenomena where the photo-diode 100 formed on the underlayer film floats from the underlayer film can be decreased. In the above mentioned configuration, it is sufficient to secure only an alignment margin between the photo-diode 100 and the lower electrode 25 in the photolithography step of the photo-diode 100, and the alignment margin can be decreased compared with Embodiment 1. As a result, the aperture ratio can be increased.

### Embodiment 3

In Embodiment 1 and Embodiment 2, a case of adhesion of the first passivation film 8 and the amorphous silicon films 9, 10 and 11 partially decreasing could occur, even if rare. This is because of organic contamination on the first passivation film 8 due to the atmosphere in the clean room. As a result, peeling of the amorphous silicon film may occur, and the defect rate increases.

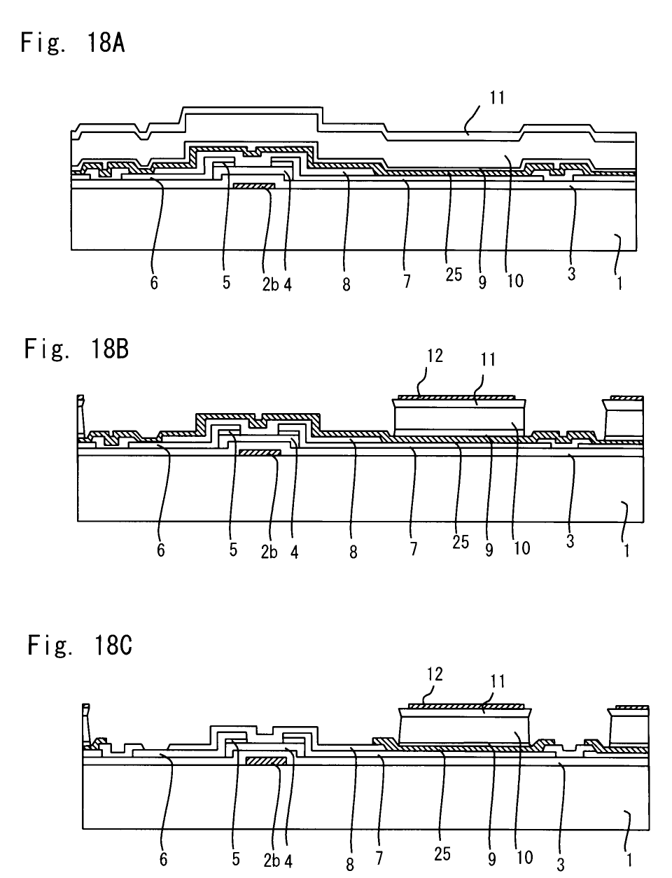

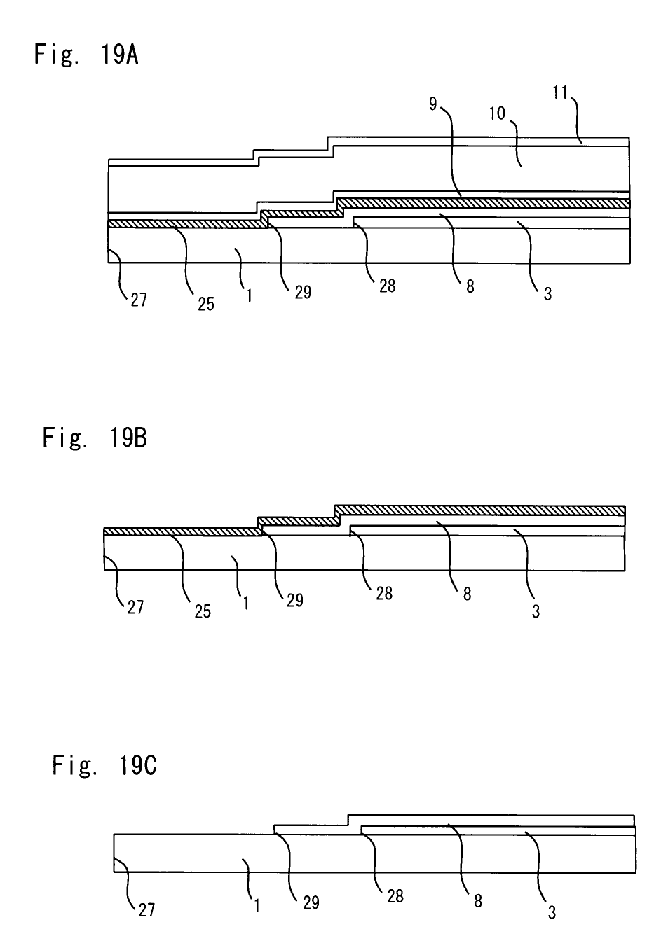

A configuration for preventing the peeling of amorphous silicon film in Embodiment 3 will be described. The configuration around the photo-diode 100 and TFT array substrate will be described with reference to FIG. 18A to FIG. 18C and FIG. 19A to FIG. 19C. FIG. 18A to FIG. 18C and FIG. 19A to FIG. 19C are cross-sectional views depicting the locations corresponding to FIG. 13 and FIG. 14 for each step. Embodiment 3 is characterized in the manufacturing method thereof. The TFT substrate completed by the manufacturing method of Embodiment 3 has roughly the same configuration as Embodiment 2 shown in FIG. 13 and FIG. 14.

Now the manufacturing method will be described. The manufacturing method, up to forming the contact hole CH1 by the fifth photolithography, is the same as Embodiment 1 and Embodiment 2, so description thereof is omitted. In Embodiment 3, the fourth conductive thin film to be the lower electrode 25 of the photo-diode 100 is deposited after forming the contact hole CH1. Depositing the fourth conductive thin film by a sputtering method, for example, can be used. For the fourth conductive thin film, a high melting point metal film, such as Cr, is deposited. Embodiment 3 is characterized in that patterning is performed after the amorphous silicon, on which the lower electrode 25 is layered, is formed.

Then, as FIG. 18A and FIG. 19A show, the P (phosphorus)-doped amorphous silicon film 9, intrinsic amorphous silicon film 10 and B (boron)-doped amorphous silicon film 11, for constituting the photo-diode 100, are sequentially deposited by a plasma CVD method in a same film deposition chamber while maintaining the vacuum state. In other words, the amorphous silicon films 9, 10 and 11 are deposited without patterning the fourth conductive film. Therefore the amorphous silicon films 9, 10 and 11 are deposited in a state where the fourth conductive thin film is formed roughly on an entire surface.

Then a non-crystal transparent conductive film is deposited by a sputtering method using one of the targets: IZO, ITZO and ITSO. After depositing the non-crystal transparent conductive film, a resist (not illustrated) is formed in the sixth photolithography step. And etching is performed using oxalic acid, for example, and the transparent electrode 12 is formed by patterning.

Then a resist pattern is formed in the seventh photolithography step. The resist pattern is one size bigger than the pattern of the transparent electrode 12, and comes inside the edge of the opening of the contact hole CH1. Then as FIG. 18B and FIG. 19B show, the three amorphous layers, that is, the P (phosphorus)-doped amorphous silicon film 9, the intrinsic amorphous silicon film 10 and the B (boron)-doped amorphous silicon film 11 are patterned. Thereby the photo-diode comprised of the three-layer structure is formed.

Then a resist pattern, which is one size bigger than the pattern of the amorphous silicon films 9, 10 and 11, is formed in a photolithography step. And as FIG. 18C and FIG. 19C show, the fourth conductive thin film to be the lower electrode 25 is patterned.

The manufacturing method after forming the lower electrode 25 is the same as the method used for steps after forming the layered amorphous silicon in Embodiment 1 and Embodiment 2, so description thereof is omitted. By this manufacturing method, not only peeling of the amorphous silicon film at the substrate edge can be prevented, but also peeling of the amorphous silicon film on the first passivation film 8 in the TFT array structure and peeling of the amorphous silicon film inside the contact hole CH1 can be prevented.

In the description of the present embodiment, the photo-diode 100 encloses the lower electrode 25, but peeling of the amorphous silicon film can be prevented even with the configuration shown in FIG. 16 and FIG. 17.

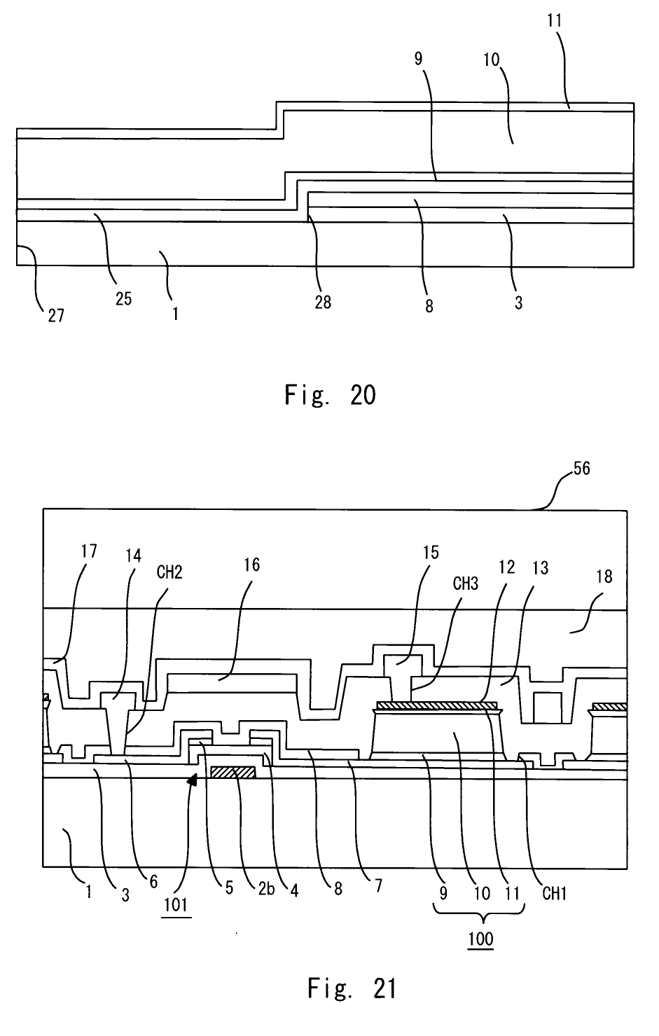

In the description of the substrate edge of the present embodiment, the edge 28 of the gate insulation film 3 is covered with the first passivation film 29, but the form shown in FIG. 20 may be used instead. In other words, the peeling of the amorphous silicon film can also be prevented in the state shown in FIG. 20, instead of the state shown in FIG. 19A. In this way, a photo-sensor, in which peeling of the amorphous silicon film is prevented, can also be manufactured by a method that is different from Embodiment 2.

The TFT described in Embodiments 1, 2 and 3 are a reverse-stagger channel etch type using amorphous silicon, but a polysilicon TFT or MOS using crystal silicon, may also be used, and a device having a switching function and a photo-diode may be combined.

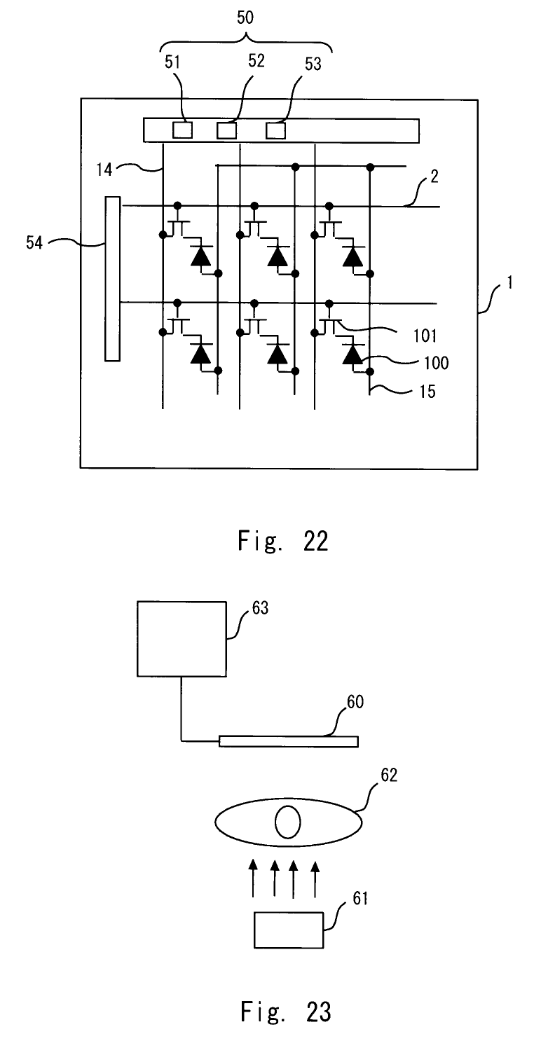

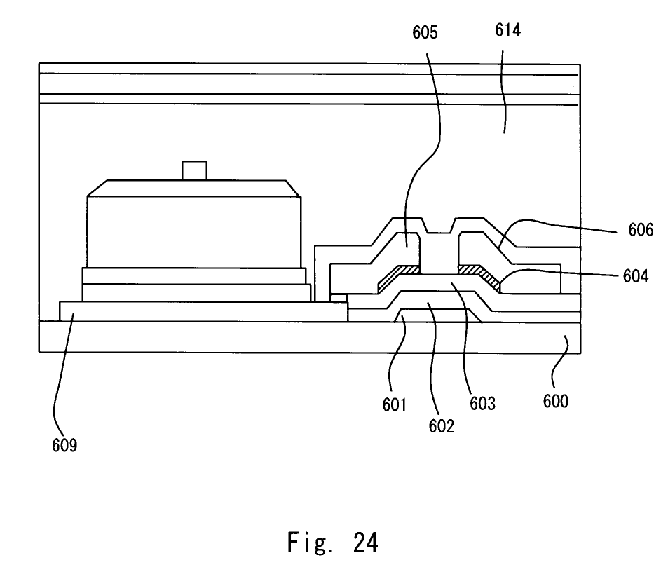

Using the array substrate created as mentioned above, a photo-sensor, such as an x-ray imaging device, may be manufactured by a known method. The x-ray imaging device can be created by depositing a scintillator 56 made from CsI, which converts an x-ray into visible light, on the fourth passivation film 18 shown in FIG. 2 or an upper layer. Thereby, the photo-sensor is formed as shown in FIG. 21. Then, connecting a digital board 50 having a low noise amplifier 51, an A/D converter 52, and so on, a driver board 54 for driving the TFT, and a read board 53 for reading electric charges (as shown in FIG. 22). In FIG. 22, the digital board 50 incorporates the read board 53. Thereby an x-ray imaging display device is formed as shown in FIG. 23. An X-ray source 61 which irradiate the human body 62 with x-ray is provided with the x-ray imaging device. The photo-sensor 60 detects x-ray passing the human body 62. An image processor 63 image-processes signal which is detected by the photo-sensor 60. Thereby an x-ray image is displayed on a monitor of the x-ray imaging device.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A photo-sensor having a TFT array substrate that has an element region in which thin film transistors are arranged in an array, comprising:
a passivation film which is provided above the thin film transistor, and in which a contact hole is formed; and
a photo-diode which is connected to a drain electrode of the thin film transistor via the contact hole, wherein
the passivation film and a gate insulation film at an edge of the TFT array substrate are removed in a peripheral area outside the element region of the substrate, and
an edge of the passivation film in the peripheral area is formed at the same position as an edge of the gate insulation film in the peripheral area, or outside the edge of the gate insulation film in the peripheral area.

2. The photo-sensor according to claim 1, further comprising a lower electrode formed on the drain electrode in the contact hole, wherein the photo-diode is connected to the drain electrode via the lower electrode.

3. The photo-sensor according to claim 2, wherein the lower electrode extends from inside the contact hole onto the passivation film, and the photo-diode is enclosed in the contact hole.

4. The photo-sensor according to claim 2, wherein the lower electrode extends from inside the contact hole onto the passivation film, and the photo-diode is formed outside the contact hole.

5. The photo-sensor according to claim 1, wherein a scintillator is formed on an upper layer than the passivation film, and a digital board having at least a low noise amplifier and an A/D comparator, a driver board for driving the thin film transistors, and a read board for reading electric charges, are connected.

6. The photo-sensor according to claim 5, having a function to perform x-ray imaging display by converting an x-ray into visible light using the scintillator.

7. A manufacturing method for a photo-sensor having a TFT array substrate that has an element region in which thin film transistors are arranged in an array, and a peripheral area outside the element region,
the method comprising steps of:
forming a thin film transistor above the substrate;
forming a passivation film having a contact hole above a drain electrode of the thin film transistor; and
forming a photo-sensor above the passivation film, wherein the passivation film and a gate insulation film at an edge of the substrate are removed in a peripheral area outside the element region where the thin film transistors are formed on the substrate, and
an edge of the passivation film in the peripheral area is formed at the same positions as an edge of the gate insulation film in the peripheral area of the substrate, or outside an edge of the gate insulation film in the peripheral area of the substrate.

8. The manufacturing method for a photo-sensor according to claim 7, further comprising a step of removing the gate insulation film in the peripheral area, using a mask pattern for patterning the passivation film, after the step of forming the passivation film on the thin film transistor.

9. The manufacturing method for a photo-sensor according to claim 7, further comprising a step of forming a lower electrode extending from inside the contact hole onto the passivation film after the step of forming the passivation film having the contact hole above the drain electrode of the thin film transistor, wherein the photo-diode is enclosed in the contact hole on the lower electrode.

10. The manufacturing method for a photo-sensor according to claim 8, further comprising a step of forming a lower electrode extending from inside the contact hole onto the passivation film after the step of forming the passivation film having the contact hole above the drain electrode of the thin film transistor, wherein the photo-diode is enclosed in the contact hole on the lower electrode.

11. The manufacturing method for a photo-sensor according to claim 7, further comprising a step of forming a lower electrode extending from inside the contact hole onto the passivation film after the step of forming the passivation film having the contact hole above the drain electrode of the thin film transistor, wherein the photo-diode is formed outside the contact hole.

12. The manufacturing method for a photo-sensor according to claim 8, further comprising a step of forming a lower electrode extending from inside the contact hole onto the passivation film after the step of forming the passivation film having the contact hole above the drain electrode of the thin film transistor, wherein the photo-diode is formed outside the contact hole.
